(19) United States
(12) Patent Application Publication
(10) Pub. No.: US 2006/0057845 A1
(43) Pub. Date: Mar. 16, 2006

(54) Method of forming nickel-silicon compound, semiconductor device, and semiconductor device manufacturing method

(75) Inventors: Mitsumasa Koyanagi, Natori-shi (JP); Hiroyuki Kurino, Gifu-shi (JP); Toshiaki Kurino, Gifu-shi (JP); Jeoung Chill Shim, Sendai-shi (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Semiconductor Technology Academic Research Center, Yokohama-shi (JP)

(21) Appl. No.: 11/207,562

(22) Filed: Aug. 19, 2005

(30) Foreign Application Priority Data
Aug. 19, 2004 (JP) 2004-239457

(51) Int. Cl. H01L 21/44

(52) U.S. Cl. 438/682

(57) ABSTRACT

There is disclosed a method of forming a nickel film on a silicon substrate or a silicon film, followed by applying an annealing process such that a final annealing temperature TH is in the range of 500° C.<TH≦600° C. to form a nickel-silicon compound, the method comprising a first annealing step of, by using an annealing device configured to change an annealing temperature in a stepwise manner, heating the substrate up to a first annealing temperature close to 400° C., followed by annealing the substrate at the first annealing temperature for a predetermined period, and a second annealing step of, by using the annealing device, heating the substrate up to a second annealing temperature which is the final annealing temperature TH, followed by annealing the substrate at the second annealing temperature for a predetermined period.

### CROSS-REFERENCE TO RELATED APPLICATIONS

This application is based upon and claims the benefit of priority from prior Japanese Patent Application No. 2004-239457, filed Aug. 19, 2004, the entire contents of which are incorporated herein by reference.

### BACKGROUND OF THE INVENTION

1. Field of the Invention

The present invention relates to a technique of improving the electrical characteristics of a semiconductor device, and more particularly, to a nickel-silicon compound forming method for improving the electrical properties of a transistor, a semiconductor apparatus, and a semiconductor apparatus manufacturing method.

2. Description of the Related Art

In recent years, a variety of semiconductor apparatuses including LSIs have remarkably progressed with downsizing or high integration of a variety of semiconductor elements such as transistors. One such factor is that, for example, the ON resistance of a transistor decreases due to downsizing of the transistor, so that a large current can be supplied by a transistor of small size.

However, the parasitic resistance of a source/drain and a gate which are principal portions of the transistor cannot be ignored due to a decrease in ON resistance of the transistor. For example, in order to reduce the parasitic resistance of the source/drain and gate, a compound called a silicide or salicide which is a metal-silicon compound has been recently used. For example, as a material for a silicide, titanium (Ti), tungsten (W), cobalt (Co) and the like are employed in general.

However, at the present stage at which a transistor gate size is equal to or smaller than 50 nm, attention is paid to nickel (Ni) as a material for a silicide having a lower resistance. For example, nickel mono-silicide (NiSi) is smaller in contact resistance or ratio resistance as compared with a silicide such as Ti, W, or Co. Thus, NiSi is expected as a material for a silicide or salicide which forms principal parts of a future transistor.

According to a general semiconductor apparatus manufacturing process, it is ideal that an NiSi film which can endure a temperature which is as high as possible be formed. In general, after an Ni film has been formed on an Si film, an NiSi film is formed by fully heating the formed film. When an Ni silicide is produced in accordance with this method, a low resistance cannot be obtained only at a temperature close to 600° C. in the case of Ni having a thickness of 10 nm, depending on the thickness of the Ni film (for example, refer to D.-X. Xu, et al, Thin Solid Film 326 (1998) pp. 1433 to 150). This is because NiSi causes coagulation or its composition is changed to NiSi₂, and then, the ratio resistance increases.

In order to avoid such a problem, there is proposed a stepwise annealing technique of repeating a process for heating a substrate of the order of 50° C. and annealing the substrate at that temperature for several tens of seconds until a final annealing temperature has been reached. However, this method causes an increase in processing time, which becomes a factor of inhibiting application of this method to a variety of semiconductor apparatuses including an LSI.

On the other hand, there is a method of providing a metal film such as Ir or Co between an Ni film and an Si substrate in order to produce a rigid Ni silicide up to a high temperature (for example, refer to U.S. Pat. No. 6,506,637 B2). However, the method increases the steps of manufacturing the semiconductor apparatus.

As described above, conventionally, in a method of forming an Ni silicide on a source/drain and a gate in order to improve the electrical properties of a transistor, there has been a problem that, if stepwise annealing is carried out of the order of 50° C. on a step-by-step basis in order to form a stable silicide up to a high temperature, a processing time is extended. In addition, in a method of inserting a metal film such as Ir or Co between an Ni film and an Si substrate, there has been a problem that wasteful steps increase and an unnecessary metal film remains.

### BRIEF SUMMARY OF THE INVENTION

According to a first aspect of the present invention, there is provided a method of forming a nickel film on a silicon substrate or a silicon film, followed by applying an annealing process such that a final annealing temperature TH is in the range of 500° C.<TH≦600° C. to form a nickel-silicon compound, the method comprising: a first annealing step of, by using an annealing device configured to change an annealing temperature in a stepwise manner, heating the substrate up to a first annealing temperature close to 400° C., followed by annealing the substrate at the first annealing temperature for a predetermined period; and a second annealing step of, by using the annealing device, heating the substrate up to a second annealing temperature which is the final annealing temperature TH, followed by annealing the substrate at the second annealing temperature for a predetermined period.

According to a second aspect of the present invention, there is provided a method of forming a nickel film on a silicon substrate or a silicon film, followed by applying an annealing process such that a final annealing temperature TH is in the range of 600° C.<TH≦700° C. to form a nickel-silicon compound, the method comprising: a first annealing step of, by using an annealing device configured to change an annealing temperature in a stepwise manner, heating the substrate up to a first annealing temperature close to 400° C., followed by annealing the substrate at the first annealing temperature for a predetermined period; a second step of, by using the annealing device, heating the substrate up to a second annealing temperature close to 600° C., followed by annealing the substrate at the second annealing temperature for a predetermined period; and a third step of, by using the annealing device, heating the substrate up to a third annealing temperature which is the final annealing temperature TH, followed by annealing the substrate at the third annealing temperature for a predetermined period.

According to a third aspect of the present invention, there is provided a method of forming a nickel film on a silicon substrate or a silicon film, followed by applying an annealing process such that a final annealing temperature TH is higher than 700° C. to form a nickel-silicon compound, the method comprising: a first annealing step of, by using an annealing device configured to change an annealing temperature in a stepwise manner, heating the substrate up to a first annealing temperature close to 400° C., followed by annealing the substrate at the first annealing temperature for a predetermined period; a second annealing step of, by using the annealing device, heating the substrate up to a second annealing temperature close to 600° C., followed by annealing the substrate at the second annealing temperature for a predetermined period; a third annealing step of, by using the annealing device, heating the substrate to a third annealing temperature close to 700° C., followed by annealing the substrate at the third annealing temperature for a predetermined period; and a step of increasing the annealing temperature within 50° C. in a stepwise manner from a temperature close to 700° C. up to a fourth annealing temperature which is the final annealing temperature TH, and annealing the substrate in each annealing step for a predetermined period.

According to a fourth aspect of the present invention, there is provided a method of forming a nickel film on a silicon substrate or a silicon film, followed by applying an annealing process to form a nickel-silicon compound, the method comprising: by using an annealing device configured to change an annealing temperature in a stepwise manner, in the case where a final annealing temperature TH is equal to or higher than 500° C., carrying out one-step annealing for, in a first annealing step, heating the substrate up to a first annealing temperature which is the final annealing temperature TH, followed by annealing the substrate at the first annealing temperature; in the case of 500° C.<TH≦600° C., carrying out two-step annealing for, in a first annealing step, heating the substrate up to a first annealing temperature close to 400° C., followed by annealing the substrate at the first annealing temperature for a predetermined period; and, in a second annealing step, heating the substrate up to a second annealing temperature which is the final annealing temperature TH, followed annealing the substrate at the second annealing temperature for a predetermined period; in the case of 600° C.<TH≦700° C., carrying out three-step annealing for, in a first annealing step, heating the substrate up to a first annealing temperature, followed by annealing the substrate at the first annealing temperature for a predetermined period; in a second annealing step, heating the substrate up to a second annealing temperature close to 600° C., followed by annealing the substrate at the second annealing temperature for a predetermined period; and in a third annealing step, heating the substrate up to a third annealing temperature which is the final annealing temperature TH, followed by annealing the substrate at the third annealing temperature at a predetermined period; when TH>700° C., carrying out multi-step annealing for, in a first annealing step, annealing the substrate up to a first annealing temperature, followed by annealing the substrate at the first annealing temperature for a predetermined period; in a second annealing step, heating the substrate up to a second annealing temperature, followed by annealing the substrate at the second annealing temperature for a predetermined period; in a third annealing step, heating the substrate up to a third annealing temperature close to 700° C., followed by annealing the substrate at the third annealing temperature for a predetermined period; and increasing the annealing temperature within 50° C. in a stepwise manner from the temperature close to 700° C. up to a fourth annealing temperature which is the final annealing temperature. TH and annealing the substrate in each annealing step for a predetermined period.

According to a fifth aspect of the present invention, there is provided a semiconductor apparatus including a nickel-silicon compound formed by the nickel-silicon compound forming method according to the first aspect of the present invention.

According to a sixth aspect of the present invention, there is provided a semiconductor apparatus including a nickel-silicon compound formed by the nickel-silicon compound forming method according to the second aspect of the present invention.

According to a seventh aspect of the present invention, there is provided a semiconductor apparatus including a nickel-silicon compound formed by the nickel-silicon compound forming method according to the third aspect of the present invention.

According to an eighth aspect of the present invention, there is provided a semiconductor apparatus including a nickel-silicon compound formed by the nickel-silicon compound forming method according to the fourth aspect of the present invention.

According to a ninth aspect of the present invention, there is provided a semiconductor apparatus manufacturing method including the nickel-silicon compound forming method according to the first aspect of the present invention.

According to a tenth aspect of the present invention, there is provided a semiconductor apparatus manufacturing method including the nickel-silicon compound forming method according to the second aspect of the present invention.

According to an eleventh aspect of the present invention, there is provided a semiconductor apparatus manufacturing method including the nickel-silicon compound forming method according to the third aspect of the present invention.

According to a twelfth aspect of the present invention, there is provided a semiconductor apparatus manufacturing method including the nickel-silicon compound forming method according to the fourth aspect of the present invention.

### BRIEF DESCRIPTION OF THE SEVERAL VIEWS OF THE DRAWING

FIG. 1 is a view showing a relationship between a processing time and a temperature in a stepwise annealing method;

FIG. 2 is a view showing a relationship between a processing time and a temperature in a two-step annealing method;

FIG. 3 is a view showing a relationship between a processing time and a temperature in a single-step annealing method;

FIG. 4 is a view showing a heating temperature and a sheet resistance in the single-step annealing;

FIG. 5 is a view showing a relationship between a processing time and a temperature in the two-step annealing method;

FIG. 6 is a view showing a relationship between a heating temperature and a sheet resistance in the two-step annealing;

FIG. 7 is a view showing a relationship between a processing time and a temperature in a three-step annealing method;

FIG. 8 is a view showing a relationship between a heating temperature and a sheet resistance in the three-step annealing;

FIG. 9 is a view for explaining an optimal annealing method utilizing a difference in final annealing temperature;

FIG. 10 is a view for explaining an annealing method in the case where a final annealing temperature is equal to or higher than 700° C.;

FIG. 11 is a view showing a change of a sheet resistance in the annealing method shown in FIG. 10;

FIG. 12 is a structural cross section in one process according to manufacture of a MOS transistor;

FIG. 13 is a structural cross section in a process which follows the process shown in FIG. 12 according to the manufacture of the MOS transistor;

FIG. 14 is a structural cross section in a process which follows the process shown in FIG. 13 according to the manufacture of the MOS transistor; and

FIG. 15 is a structural cross section in a process which follows the process shown in FIG. 14 according to the manufacture of the MOS transistor.

### DETAILED DESCRIPTION OF THE INVENTION

Hereinafter, an embodiment of the present invention will be described with reference to the accompanying drawings.

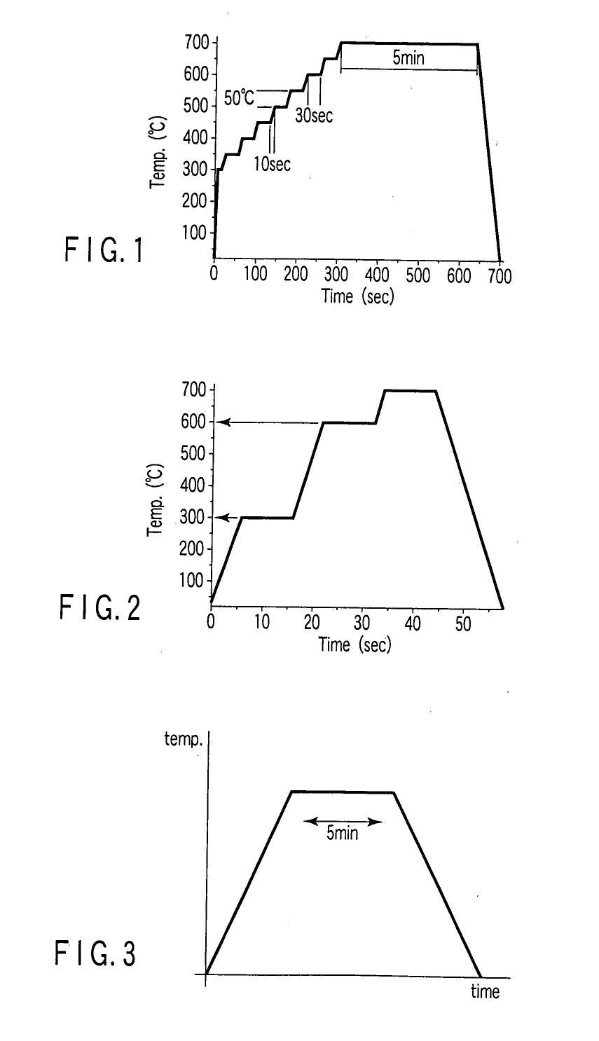

FIG. 1 shows a stepwise annealing technique which was already filed by the Inventors (Japanese Patent Application No. 2003-323434, filed Sep. 16, 2003. After heating has been fully carried out up to 300° C. while an Ni film has been formed on an Si substrate, a temperature is increased in a stepwise manner (50° C. for 10 seconds), heat treatment is carried out for 30 seconds on a step-by-step basis, and heat treatment is applied for 5 minutes at a final temperature of 700° C. In this method, an Ni silicide having a low resistance up to a high temperature can be produced.

In this method, however, there is a problem that a time required for processing is as large as about 10 minutes and a large amount of heat is applied to a device. In order to solve this problem, the Inventors have studied a method which enables nickel silicidation for a shorter period.

There are two advantageous effects of the steps in the stepwise annealing method. One of them is that a temperature is increased in a stepwise manner, thus making it possible to reduce a temperature difference between an inside and an outside of a sample. The other is that annealing can be carried out for a predetermined period of time at a temperature at which a phase change from Ni+Si to Ni₂Si occurs; a phase change to NiSi further occurs; and then, a phase change to NiSi₂ occurs. If the second advantageous effect is attained, it is believed that a large number of steps shown in FIG. 1 can be significantly reduced.

FIG. 2 is a view showing a case in which it is assumed that an annealing temperature at which a phase change occurs is 300° C. and 600° C. This is not an actual case. If it is possible to experimentally know what minimum time is required for a phase change, a time required for silicidation can be reduced. Experimentation for that purpose has been carried out.

At the first stage of experimentation, bulk Si having an Ni film of 20 nm in thickness deposited thereon was put in a rapid thermal annealing (RTA) device, and a resistance change was observed at each temperature. This experimentation is intended to check whether or not a resistance change occurs at a specific temperature. This is because it is believed that a phase change occurs at a temperature at which a resistance change occurs. Thus, an annealing time at each temperature was set to 5 minutes in order to check that a phase change occurs. Temperature rise rates were set to 200° C., 100° C., and 50° C. per second.

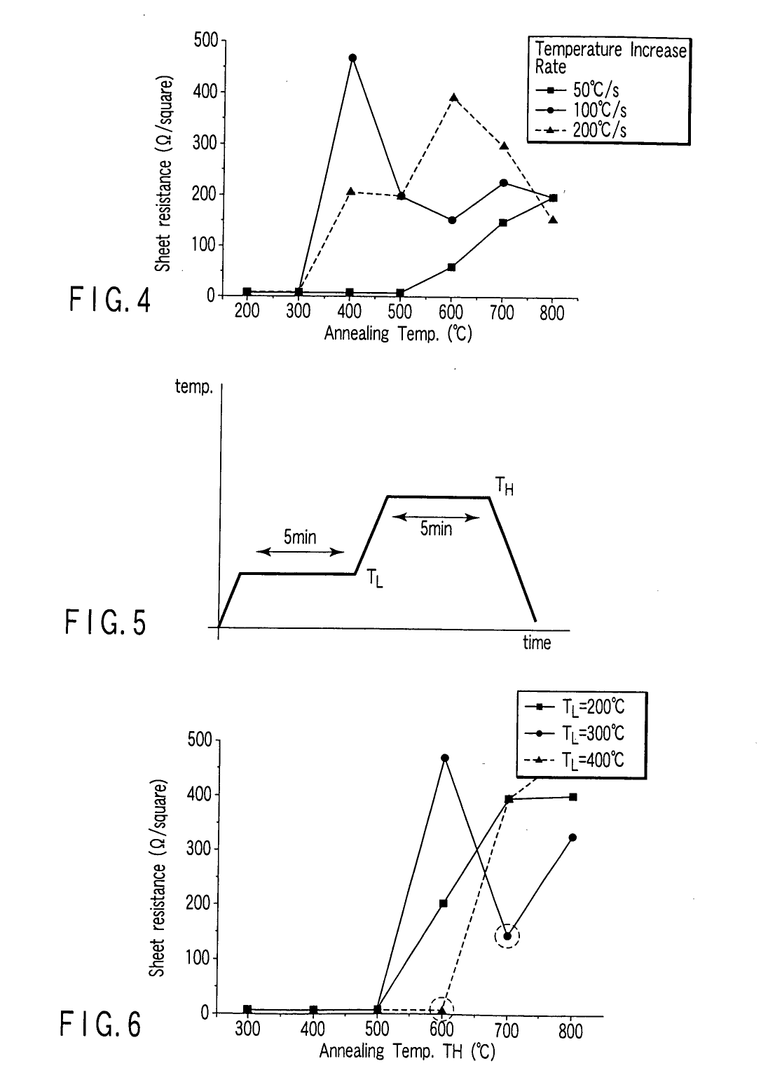

As shown in FIGS. 3 and 4, no specific resistance change was observed in one-step annealing. In addition, in the case of temperature rise rates of 200° C./sec and 100° C./sec, an increase in resistance was observed if 300° C. was exceeded. Thus, experimentation continued in the case of a temperature rise rate of 50° C./sec. If a temperature rise rate is too low, a total processing time is extended. Thus, it is desirable that the temperature rise rate is equal to or higher than 50° C./sec.

As shown in FIG. 5, a two-step annealing method was prepared, annealing was carried out at two temperatures, and it was observed whether or not a resistance change occurs. The provided two-step annealing method is provided as a method in which, for example, in the case where an annealing temperature TL in a first step is 300° C., a temperature is increased up to 300° C. at a temperature rise rate of 50° C./sec; the temperature rises up to 300° C., and is maintained at 300° C. for 5 minutes; and then, in a second step (final step), a temperature is increase up to a desired temperature (final annealing temperature) TH at a temperature rise rate of 50° C./sec; the temperature rises up to a desired temperature; the desired temperature is maintained for 5 minutes; and the temperature is reduced up to 20° C. at a temperature fall rate of 50° C./sec.

An experimentation result obtained in accordance with such a temperature profile is shown in FIG. 6. In a case where the annealing temperature TL was set to 300° C. in the first step and the annealing temperature TH in the second step (the final step) was set to 700° C., and a case where TL was set to 400° C. and TH was set to 600° C., respectively, a resistance change was observed. Based on this fact, an attempt is made to execute: an annealing method of inserting the step (dwell time) of constantly maintaining a temperature at 300° C. and at 700° C., followed by carrying out heating up to a temperature higher than the maintained temperature; and an annealing method of inserting the step of constantly maintaining a temperature at 400° C. and at 600° C., followed by carrying out heating up to a temperature higher than the maintained temperature. The dwell time was changed to 5 minutes, 30 seconds, 10 seconds, and the like.

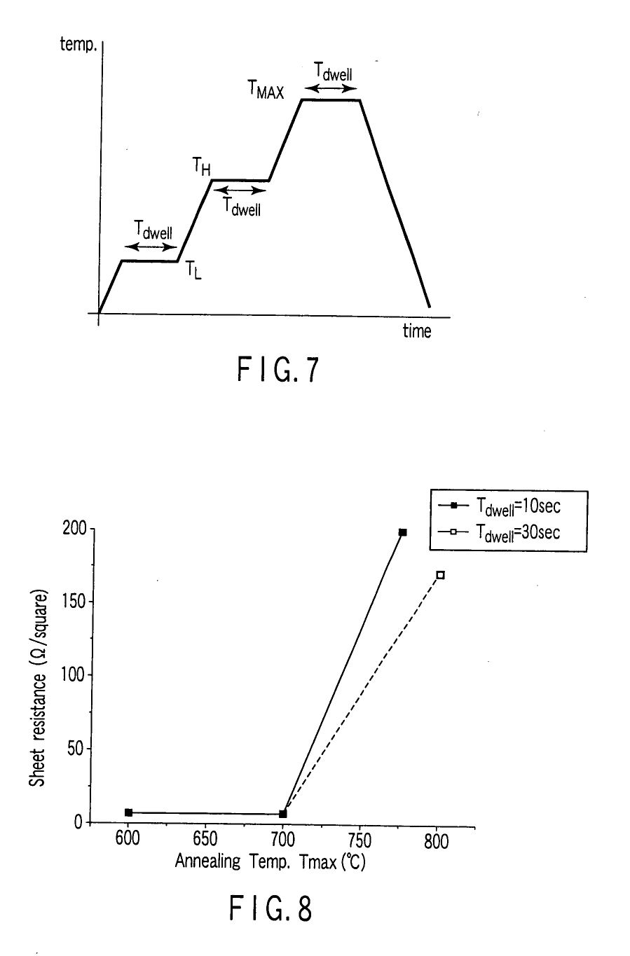

As a result, as shown in FIG. 6, no particular low resistance was observed in the case of 300° C. and 700° C. However, in the case of 400° C. and 600° C., a resistance was obtained up to 700° C. In addition, as shown in FIGS. 7 and 8, even if the dwell time was set to 10 seconds, such a low resistance was observed. Thus, the dwell time was determined as 10 seconds. When the annealing time at the predetermined temperature is shorter than 10 seconds, a resistance rise is observed. Therefore, it is desirable that the annealing time at the predetermined temperature is equal to or longer than 10 seconds.

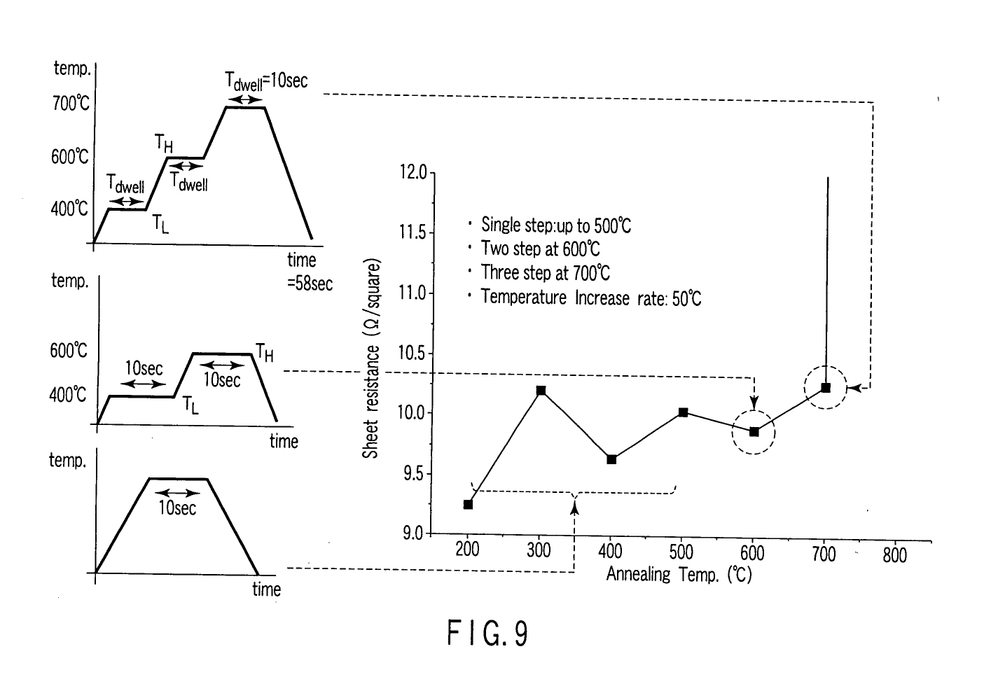

The foregoing description can be summarized as shown in FIG. 9. That is, single-step annealing is carried out such that a temperature is rapidly increased up to a comparatively low temperature up to 500° C. and the temperature is maintained for a predetermined period of time (for example, for 10 seconds). Then, after annealing, the temperature is rapidly reduced. Rapid temperature rise and fall rates each are of the order of 50° C./sec.

In the case where annealing is carried out at 600° C., two-step annealing is carried out such that: a temperature is rapidly increased up to 400° C.; the temperature is maintained for 10 seconds; the temperature is rapidly increased up to 600° C.; this temperature is maintained for 10 seconds; and annealing is carried out. When annealing is carried out at 700° C., three-step annealing is carried out through a wait time of each of 10 seconds at 400° C. and at 600° C. This makes it possible to fabricate Ni silicide having a low resistance up to a temperature which is as high as 700° C. in a sufficiently short period.

As shown in FIG. 9, in the above-described annealing method, annealing is divided into three sections of 500° C. or lower, 600° C., and 700° C., and annealing is carried out at a predetermined period at specific temperatures of 400° C. and 600° C. Thus, this annealing method is referred to as specific temperature annealing (STA). The temperatures of 400° C. and 600° C. in STA are not always strict. If the temperature is close to each of these temperatures (for example, in the range of ±10° C.), an advantageous effect similar to the above was observed.

In the case where annealing is carried out at 700° C. or higher, it is possible to produce an Ni silicide having a low resistance. Therefore, as shown in FIG. 10, stepwise annealing is employed for annealing at 700° C. or higher. In each annealing step, a temperature is increased by 50° C. in 10 seconds, and annealing is carried out for 10 seconds at the temperature. For example, when stepwise annealing is carried out from 700° C., a temperature is increased from 700° C. up to 750° C. in 10 seconds, and annealing is carried out at 750° C. for 10 seconds. Thereafter, the temperature is increased up to 800° C. in 10 seconds, and annealing is carried out at 800° C. for 10 seconds.

In this way, annealing is carried out while a temperature is increased in a stepwise manner. After the annealing has completed, the temperature is reduced up to 20° C. at a temperature fall rate of 50° C. per second, and an annealing process is terminated. This makes it possible to form a silicide having a low resistance up to a high temperature. Namely, at a comparatively low temperature up to 700° C., silicidation is carried out by STA, and at a temperature equal to or higher than 700° C., stepwise annealing is carried out. A temperature profile obtained when annealing is thus carried out is shown in FIG. 10. Although a required time has been 10 minutes or longer in conventional stepwise annealing when annealing is carried out up to 900° C., a required time is 2 minutes and 22 seconds in the method according to the present embodiment.

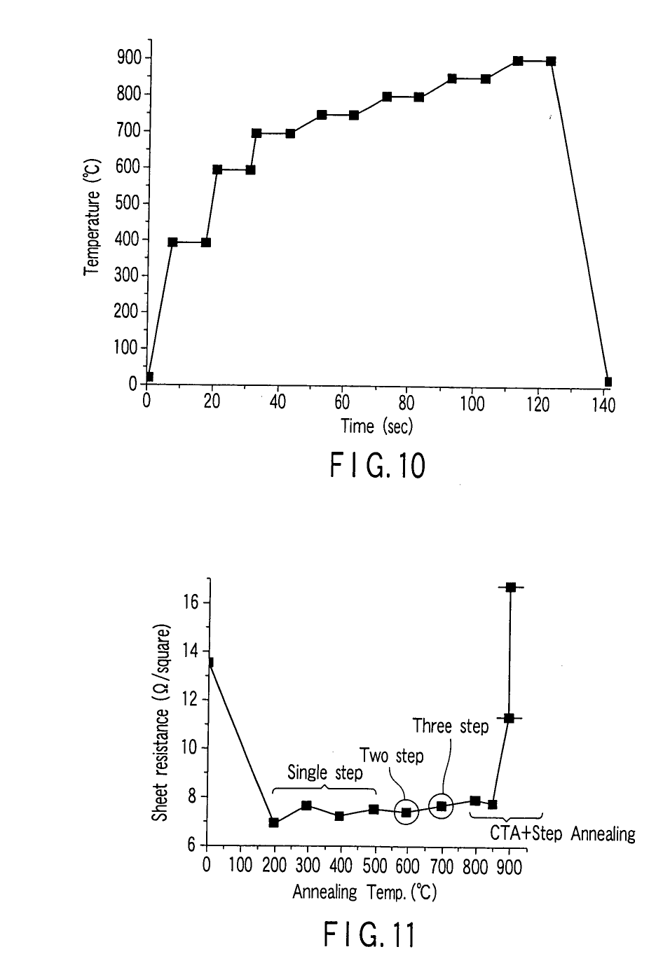

A change in sheet resistance is shown in FIG. 11. Although a low resistance was obtained up to 850° C., a resistance rapidly increased at 900° C. The data obtained at 900° C. shown in FIG. 11 indicates an error bar.

With the method according to the above-described embodiment, an annealing process for forming a nickel-silicon compound is carried out as follows, instead of reducing a temperature rise range in each step and increasing a temperature in a multi-stepwise manner. That is, the temperature is rapidly increased up to a predetermined temperature in a large temperature rise range, this temperature is maintained for a predetermined period, and annealing is carried out. After the temperature is rapidly increased to a next temperature in a large temperature rise range, this temperature is maintained for a predetermined period, and annealing is carried out, whereby a total annealing time can be reduced. Then, 400° C., 600° C., and 700° C. each are set as a temperature maintained for a predetermined period, whereby an increase in resistance of Ni silicide can be restricted.

With the method according to the above-described embodiment, Ni silicide having high heat stability can be formed on a Si substrate for a short period without causing an increased number of steps.

In the above embodiment, the Ni film has been formed on the Si substrate, thereby achieving silicidation, but the Ni film may be formed on the silicon film, thereby making it possible to achieve silicidation.

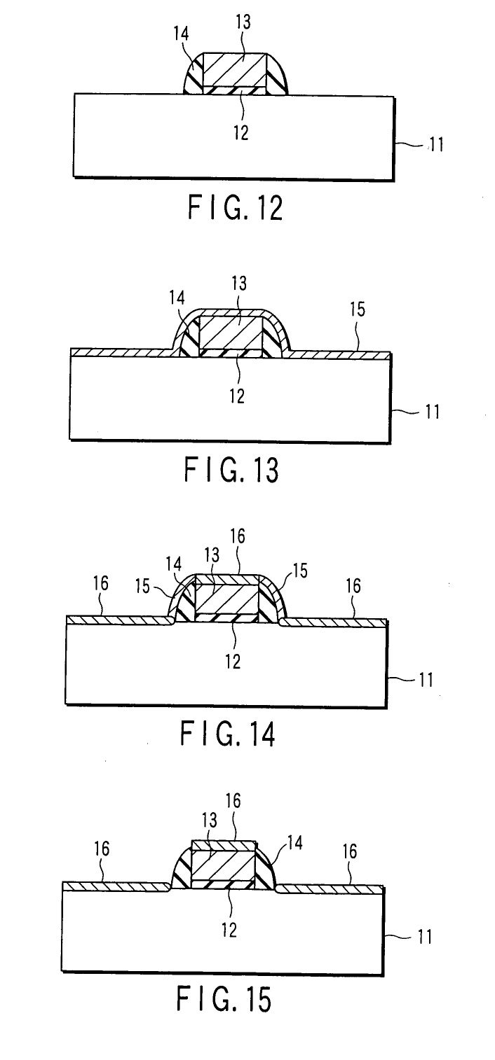

FIGS. 12 and 15 are sectional views each showing a process in the case where the above embodiment has been applied to the manufacture of a MOS transistor.

First, as shown in FIG. 12, a poly-Si film is deposited on an Si substrate 11 via a gate oxide film 12. Next, the poly-Si film is selectively etched, and the thus etched film is patterned for a gate electrode pattern, thereby forming a gate electrode 13. Then, an Si nitride film is fully deposited, and then, etched back, thereby forming a gate sidewall insulation film 14.

Next, as shown in FIG. 13, an Ni film 15 is fully sputtered, thereby forming the film having thickness of 50 nm, for example.

Next, as shown in FIG. 14, an annealing process is applied, and the Ni film 15 is silicidated. Specifically, a final annealing temperature TH is set to 800° C., the temperature is increased up to 400° C. at a rapid rate of the order of 50° C./sec, and annealing is carried out at this temperature for 10 seconds. Then, After the temperature is increased up to 600° C. of the order of 50° C./sec, annealing is carried out at this temperature for 10 seconds. Subsequently, the temperature is increased up to 700° C. of the order of 50° C./sec, and annealing is carried out at this temperature for 10 seconds.

Next, in annealing at 700° C. or higher, the stepwise annealing described previously was used. That is, a temperature is increased from 700° C. to 750° C., and annealing is carried out at 750° C. for 10 seconds. Thereafter, the temperature is increased up to 800° C. in 10 seconds, and annealing is carried out at 800° C. for 10 seconds.

In this manner, an Ni silicide film 16 is formed in a source/drain region. The Ni silicide film 16 has a high withstand voltage and a sufficiently low resistance.

Next, as shown in FIG. 15, the Ni film 15 left without being silicide is removed. In this manner, a MOS transistor using an Ni silicide for the source/drain and gate is fabricated.

As described above, according to the embodiment of the invention, an Ni silicide having high heat stability and low resistance can be formed on the Si substrate for a short period, and the low resistance of the source/drain is achieved, making it possible to contribute to the improvement of transistor characteristics.

The present invention is not limited to the above-described embodiment. Although the annealing time in 400° C., 600° C., and 700° C. has been set to 10 seconds, the annealing time can be changed as required. However, if the annealing time is shorter than the above, the advantageous effect of stepwise annealing is eliminated. Thus, it is desirable that the annealing time is equal to or longer than 10 seconds. On the other hand, if the annealing time is too long, it causes an increase in annealing time. Therefore, it is desirable that the annealing time is within several tens of seconds. In addition, it is desirable that a temperature rise up to a temperature exceeding 700° C. is equal to or lower than 50° C. per step. In this case, the temperature rise rate is of the order of 50° C. in 10 seconds, i.e., of the order of 5° C./sec.

According to the preset invention, instead of reducing a temperature rise range in each step and increasing a temperature in a multi-stepwise manner, an annealing process for forming a nickel-silicon compound is carried out in such a manner that: after the temperature is rapidly increased up to a predetermined temperature, annealing is carried out for a predetermined period; and after the temperature is rapidly increased to a next temperature, annealing is carried out for a predetermined period, whereby the total annealing time can be reduced. Then, 400° C., 600° C., and 700° C. each are set as a temperature to be rapidly increased, whereby an increase in the resistance of an Ni silicide can be restricted.

What is claimed is:

1. A method of forming a nickel film on a silicon substrate or a silicon film, followed by applying an annealing process such that a final annealing temperature TH is in the range of 500° C.<TH≦600° C. to form a nickel-silicon compound, the method comprising:
a first annealing step of, by using an annealing device configured to change an annealing temperature in a stepwise manner, heating the substrate up to a first annealing temperature close to 400° C., followed by annealing the substrate at the first annealing temperature for a predetermined period; and
a second annealing step of, by using the annealing device, heating the substrate up to a second annealing temperature which is the final annealing temperature TH, followed by annealing the substrate at the second annealing temperature for a predetermined period.

2. A method of forming a nickel-silicon compound, according to claim 1, wherein the predetermined annealing time in each said annealing step is equal to or longer than 10 seconds.

3. A method of forming a nickel-silicon compound, according to claim 1, wherein a temperature increase rate up to the annealing temperature in each said annealing step is equal to or higher than 50° C./sec.

4. A method of forming a nickel film on a silicon substrate or a silicon film, followed by applying an annealing process such that a final annealing temperature TH is in the range of 600° C.<TH≦700° C. to form a nickel-silicon compound, the method comprising:
a first annealing step of, by using an annealing device configured to change an annealing temperature in a stepwise manner, heating the substrate up to a first annealing temperature close to 400° C., followed by annealing the substrate at the first annealing temperature for a predetermined period;
a second step of, by using the annealing device, heating the substrate up to a second annealing temperature close to 600° C., followed by annealing the substrate at the second annealing temperature for a predetermined period; and
a third step of, by using the annealing device, heating the substrate up to a third annealing temperature which is the final annealing temperature TH, followed by annealing the substrate at the third annealing temperature for a predetermined period.

5. A method of forming a nickel-silicon compound, according to claim 4, wherein the predetermined annealing time in each said annealing step is equal to or longer than 10 seconds.

6. A method of forming a nickel-silicon compound, according to claim 4, wherein a temperature increase rate up to the annealing temperature in each said annealing step is equal to or higher than 50° C./sec.

7. A method of forming a nickel film on a silicon substrate or a silicon film, followed by applying an annealing process such that a final annealing temperature TH is higher than 700° C. to form a nickel-silicon compound, the method comprising:
a first annealing step of, by using an annealing device configured to change an annealing temperature in a stepwise manner, heating the substrate up to a first annealing temperature close to 400° C., followed by annealing the substrate at the first annealing temperature for a predetermined period;
a second annealing step of, by using the annealing device, heating the substrate up to a second annealing temperature close to 600° C., followed by annealing the substrate at the second annealing temperature for a predetermined period;
a third annealing step of, by using the annealing device, heating the substrate to a third annealing temperature close to 700° C., followed by annealing the substrate at the third annealing temperature for a predetermined period; and
a step of increasing the annealing temperature within 50° C. in a stepwise manner from a temperature close to 700° C. up to a fourth annealing temperature which is the final annealing temperature TH, and annealing the substrate in each annealing step for a predetermined period.

8. A method of forming a nickel-silicon compound, according to claim 7, wherein the predetermined annealing time in each said annealing step is equal to or longer than 10 seconds.

9. A method of forming a nickel-silicon compound, according to claim 7, wherein a temperature increase rate up to the annealing temperature in each said annealing step is equal to or higher than 50° C./sec.

10. A method of forming a nickel-silicon compound, according to claim 7, wherein a temperature increase rate up to each of the annealing temperatures in the first, second, and third annealing steps is equal to or higher than 50° C./sec, and a temperature increase rate in said each annealing step from the temperature close to 700° C. up to the fourth annealing temperature which is the final annealing temperature TH is of the order of 5° C./sec.

11. A method of forming a nickel film on a silicon substrate or a silicon film, followed by applying an annealing process to form a nickel-silicon compound, the method comprising:
by using an annealing device configured to change an annealing temperature in a stepwise manner,
in the case where a final annealing temperature TH is equal to or higher than 500° C., carrying out one-step annealing for, in a first annealing step, heating the substrate up to a first annealing temperature which is the final annealing temperature TH, followed by annealing the substrate at the first annealing temperature;
in the case of 500° C.<TH≦600° C., carrying out two-step annealing for, in a first annealing step, heating the substrate up to a first annealing temperature close to 400° C., followed by annealing the substrate at the first annealing temperature for a predetermined period; and, in a second annealing step, heating the substrate up to a second annealing temperature which is the final annealing temperature TH, followed annealing the substrate at the second annealing temperature for a predetermined period;
in the case of 600° C.<TH≦700° C., carrying out three-step annealing for, in a first annealing step, heating the substrate up to a first annealing temperature, followed by annealing the substrate at the first annealing temperature for a predetermined period; in a second annealing step, heating the substrate up to a second annealing temperature close to 600° C., followed by annealing the substrate at the second annealing temperature for a predetermined period; and in a third annealing step, heating the substrate up to a third annealing temperature which is the final annealing temperature TH, followed by annealing the substrate at the third annealing temperature at a predetermined period;
when TH>700° C., carrying out multi-step annealing for, in a first annealing step, annealing the substrate up to a first annealing temperature, followed by annealing the substrate at the first annealing temperature for a period; in a second annealing step, heating the substrate up to a second annealing temperature, followed by annealing the substrate at the second annealing temperature for a predetermined period; in a third annealing step, heating the substrate up to a third annealing temperature close to 700° C., followed by annealing the substrate at the third annealing temperature for a predetermined period; and increasing the annealing temperature within 50° C. in a stepwise manner from the temperature close to 700° C. up to a fourth annealing temperature which is the final annealing temperature TH and annealing the substrate in each annealing step for a predetermined period.

12. A method of forming a nickel-silicon compound, according to claim 11, wherein the predetermined annealing time in each said annealing step is equal to or longer than 10 seconds.

13. A method of forming a nickel-silicon compound, according to claim 11, wherein a temperature increase rate up to the annealing temperature in each said annealing step is equal to or higher than 50° C./sec.

14. A method of forming a nickel-silicon compound, according to claim 11, wherein a temperature increase rate up to each of the annealing temperatures in the first, second, and third annealing steps is equal to or higher than 50° C./sec, and a temperature increase rate in said each annealing step from the temperature close to 700° C. up to a fourth annealing temperature which is the final annealing temperature TH is of the order of 5° C./sec.

15. A semiconductor apparatus including a nickel-silicon compound formed by the nickel-silicon compound forming method according to claim 1.

16. A semiconductor apparatus including a nickel-silicon compound formed by the nickel-silicon compound forming method according to claim 4.

17. A semiconductor apparatus including a nickel-silicon compound formed by the nickel-silicon compound forming method according to claim 7.

18. A semiconductor apparatus including a nickel-silicon compound formed by the nickel-silicon compound forming method according to claim 11.

19. A semiconductor apparatus manufacturing method including the nickel-silicon compound forming method according to claim 1.

20. A semiconductor apparatus manufacturing method including the nickel-silicon compound forming method according to claim 4.

21. A semiconductor apparatus manufacturing method including the nickel-silicon compound forming method according to claim 7.

22. A semiconductor apparatus manufacturing method including the nickel-silicon compound forming method according to claim 11.
